(19) United States
(12) Patent Application Publication
(10) Pub. No.: US 2024/0036102 A1
(43) Pub. Date: Feb. 1, 2024

(54) ANISOTROPIC CONDUCTIVE SHEET AND ELECTRICAL INSPECTION METHOD

(71) Applicant: Mitsui Chemicals, Inc., Tokyo (JP)

(72) Inventors: Katsunori NISHIURA, Chiba-shi, Chiba (JP); Daisuke YAMADA, Hidaka-shi, SAITAMA (JP); Yuichi ITO, Ichihara-shi, Chiba (JP)

(21) Appl. No.: 18/256,433

(22) PCT Filed: Nov. 30, 2021
(86) PCT No.: PCT/JP2021/043786

§ 371 Date: Jun. 8, 2023

(30) Foreign Application Priority Data
Dec. 11, 2020 (JP) 2020-206277

(51) Int. Cl. G01R 31/28

(52) U.S. Cl. CPC G01R 31/2801

(57) ABSTRACT

This anisotropic conductive sheet (10) comprises: an insulating layer (11) having a first surface located on one side in the thickness direction, a second surface located on the other side, and a plurality of through holes (12) penetrating between the first surface and the second surface; a plurality of conductive layers (22) continuously arranged at the inner wall surface of the through holes in each of at least some of the plurality of through holes and around the openings of the through holes on the first surface; and a plurality of first grooves (14) that are arranged between the plurality of conductive layers on the first surface to insulate the conductive layers from each other, wherein the center of gravity (C2) of the opening of each through hole is set apart from the center of gravity (C1) of the respective conductive layer on the first surface.

### TECHNICAL FIELD

The present invention relates to an anisotropic conductive sheet and an electrical inspection method.

### BACKGROUND ART

Typically, an electrical inspection is performed for a semiconductor device such as a print wiring plate that is mounted in an electronic product. Typically, the electrical inspection is performed by electrically connecting a substrate of an electrical inspection apparatus (electrode have) and a terminal serving as an inspection object such as a semiconductor device, and reading the current when a predetermined voltage is applied to the terminals of the inspection object. Then, in order to reliably electrically connect the electrode of the substrate of the electrical inspection apparatus and the terminal of the inspection object, an anisotropic conductive sheet is disposed between the substrate of the electrical inspection apparatus and the inspection object.

The anisotropic conductive sheet has conductivity in the thickness direction and an insulation property in the surface direction, and is used as a probe (contact) for electrical inspection. In order to reliably electrically connect the substrate of the electrical inspection apparatus and the inspection object, the anisotropic conductive sheet is used by applying a pushing load. Therefore, it is desirable for the anisotropic conductive sheet to be elastically deformable in the thickness direction.

As such an anisotropic conductive sheet, a known electric connector includes an elastic body including a plurality of through holes extending through in the thickness direction, and a plurality of hollow conductive members joined to the inner wall surfaces of the plurality of through holes (see, for example, PTL 1). In addition, a known electric connector includes a base material sheet including a plurality of through holes extending through in the thickness direction, a plurality of conductive parts disposed in the plurality of through holes, and a plurality of conductive protruding parts configured to cover the end surfaces of the plurality of conductive parts (see, for example, PTL 2).

### CITATION LIST

### Patent Literature

PTL 1
WO2018/212277
PTL 2
Japanese Patent Application Laid-Open No. 2020-27859

### SUMMARY OF INVENTION

### Technical Problem

The electric connectors (anisotropic conductive sheets) disclosed in PTLS 1 and 2 are used with the inspection object disposed on its surface. The anisotropic conductive sheet is manufactured or used such that the center of the terminal of the inspection object is located at the center of the opening of each through hole at the surface of the anisotropic conductive sheet.

However, when the inspection object is disposed such that the center of the terminal of the inspection object is located at the center of each through hole, a large pushing load is applied to the through hole. As a result, when pressurization and depressurization through pushing are repeated, cracks and peeling occur at the conductive member or the conductive part joined on the inner wall surface of the through hole (the conductive layer on the inner wall surface of the through hole), and conduction failures occur in many cases.

In view of the above-mentioned problems, an object of the present invention is to provide an anisotropic conductive sheet and an electrical inspection method using the same with which cracks and peeling of the conductive layer can be suppressed even when pressurization and depressurization through pushing are repeated, and favorable conductivity can be maintained.

### Solution to Problem

The above-mentioned problems are solved by the following configurations.

An anisotropic conductive sheet of the present invention includes: an insulating layer including a first surface located on one side in a thickness direction, a second surface located on another side, and a plurality of through holes extending between the first surface and the second surface; a plurality of conductive layers each disposed at each of at least some of the plurality of through holes such that the plurality of conductive layers is continuous at an inner wall surface of the each of at least some of the plurality of through holes and around an opening of the each of at least some of the plurality of through holes on the first surface; and a plurality of first groove parts disposed on the first surface between the plurality of conductive layers, and configured to insulate the plurality of conductive layers, wherein on the first surface, a center of gravity of an opening of each of the plurality of through holes is separated from a center of gravity of a conductive layer of the plurality of conductive layers continuously disposed around the opening.

An electrical inspection method of the present invention includes: preparing an anisotropic conductive sheet, the anisotropic conductive sheet including: an insulating layer including a first surface located on one side in a thickness direction, a second surface located on another side, and a plurality of through holes extending between the first surface and the second surface, a plurality of conductive layers each disposed at each of at least some of the plurality of through holes such that the plurality of conductive layers is continuous at an inner wall surface of the each of at least some of the plurality of through holes and around an opening of the each of at least some of the plurality of through holes on the first surface, and a plurality of first groove parts disposed on the first surface between the plurality of conductive layers, and configured to insulate the plurality of conductive layers; and electrically connecting a terminal of an inspection object and each of the plurality of conductive layers by disposing the inspection object on the first surface such that a center of gravity of the terminal of the inspection object is separated from a center of gravity of each of the plurality of conductive layers in plan view.

### Advantageous Effects of Invention

According to the present invention, it is possible to provide an anisotropic conductive sheet and an electrical inspection method using the same with which cracks and peeling of the conductive layer can be suppressed even when pressurization and depressurization through pushing are repeated, and favorable conductivity can be maintained.

### BRIEF DESCRIPTION OF DRAWINGS

FIG. 1A is a partial plan view illustrating an anisotropic conductive sheet according to the present embodiment, and FIG. 1B is a partially enlarged sectional view of the anisotropic conductive sheet of FIG. 1A taken along line 1B-1B;

FIGS. 2A and 2B are partially enlarged plan views of a region around a through hole at a first surface of the anisotropic conductive sheet of FIG. 1;

FIG. 3A is a partially enlarged plan view of a region around the through hole at the first surface of the anisotropic conductive sheet of FIG. 1, and FIG. 3B is a partially enlarged sectional view of the anisotropic conductive sheet of FIG. 1A taken along line 1B-1B;

FIGS. 4A to 4D are partially enlarged sectional views illustrating a manufacturing method of the anisotropic conductive sheet according to the present embodiment;

FIG. 5 is a sectional view illustrating an electrical inspection apparatus according to the present embodiment;

FIG. 6A is a partially enlarged plan view illustrating an electrical inspection method according to the present embodiment, and FIG. 6B is a partially enlarged sectional view illustrating the electrical inspection method according to the present embodiment;

FIGS. 7A and 7B are partially enlarged plan views of a region around a through hole at a first surface of an anisotropic conductive sheet according to a modification;

FIGS. 8A and 8B are partially enlarged plan views illustrating a modification of an opening shape of the through hole;

FIG. 9 is a partially enlarged sectional view illustrating the anisotropic conductive sheet according to the modification; and

FIG. 10A is a partially enlarged plan view illustrating an electrical inspection method according to a modification, and FIG. 10B is a partially enlarged sectional view illustrating an electrical inspection method using the anisotropic conductive sheet according to the modification.

### DESCRIPTION OF EMBODIMENTS

### 1. Anisotropic Conductive Sheet

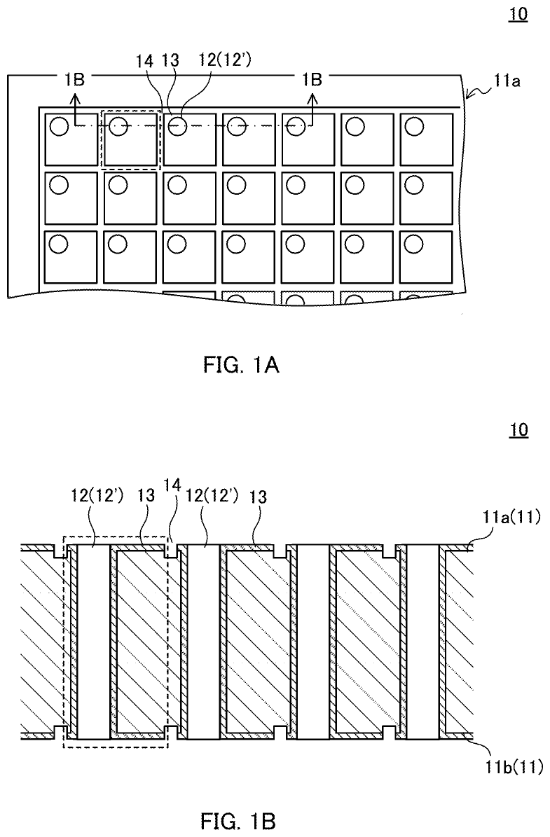

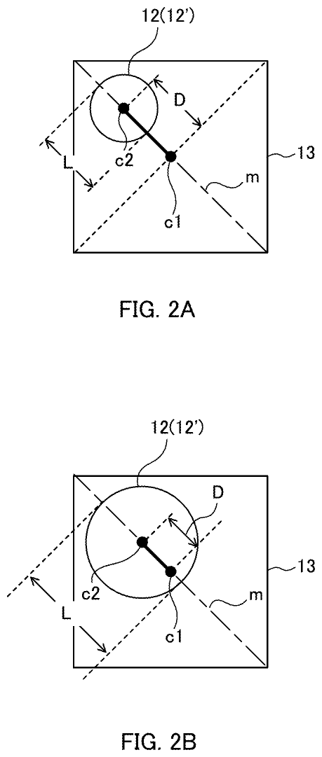

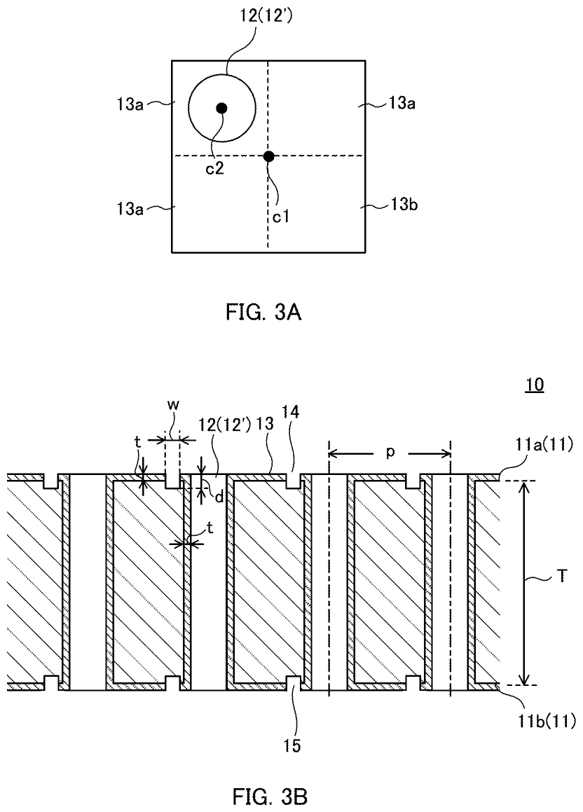

FIG. 1A is a partially enlarged plan view of anisotropic conductive sheet 10 according to the present embodiment, and FIG. 1B is a partially enlarged sectional view of anisotropic conductive sheet 10 of FIG. 1A taken along line 1B-1B. FIGS. 2A and 2B are partially enlarged plan views of a region around through hole 12 at first surface 11a of anisotropic conductive sheet 10 of FIG. 1. FIG. 3A is a partially enlarged plan view of a region around the through hole at the first surface of the anisotropic conductive sheet of FIG. 1, and FIG. 3B is a partially enlarged sectional view of the anisotropic conductive sheet of FIG. 1A taken along line 1B-1B. The drawings described below are schematic views, and scale and other details may differ from the actual figures.

As illustrated in FIGS. 1A and 1B, anisotropic conductive sheet 10 includes insulating layer 11 including a plurality of through holes 12, a plurality of conductive layers 13 disposed in a manner corresponding to the plurality of through holes 12 (see, for example, two conductive layers 13 surrounded by the broken line in FIG. 1), and a plurality of first groove parts 14 and a plurality of second groove parts 15 disposed between the plurality of conductive layers 13. Such an anisotropic conductive sheet 10 includes a plurality of hollows 12′ surrounded by conductive layers 13.

In the present embodiment, preferably, inspection objects are disposed on first surface 11a of insulating layer 11 (one surface of anisotropic conductive sheet 10).

### 1-1. Insulating Layer 11

Insulating layer 11 includes first surface 11a located on one side in the thickness direction, second surface 11b located on the other side in the thickness direction, and the plurality of through holes 12 extending between first surface 11a and second surface 11b (see FIGS. 1A and 1i).

Insulating layer 11 has an elasticity to elastically deform under a pressure applied in the thickness direction. Specifically, preferably, insulating layer 11 includes at least an elastic body layer. Preferably, the elastic body layer contains a cross-linked elastomer composition.

Preferable examples of the elastomer contained in the elastomer composition include, but not limited to, silicone rubber, urethane rubber (urethane polymer), acrylic rubber (acrylic polymer), ethylene-propylene-diene copolymer (EPDM), chloroprene rubber, styrene-butadiene copolymer, acrylic nitrile-butadiene copolymer, polybutadiene rubber, natural rubber, polyester-based thermoplastic elastomer, olefin-based thermoplastic elastomer, and fluorinated rubber. In particular, silicone rubber is preferable.

The elastomer composition may further contain a crosslinking agent as necessary. The crosslinking agent may be selected as necessary in accordance with the type of the elastomer. Examples of the crosslinking agent of the silicone rubber include addition reaction catalysts such as metals, metal compounds, and metal complexes (such as platinum, platinum compounds, and their complexes) having catalytic activity for hydrosilylation reactions; and organic peroxides such as benzoyl peroxide, bis-2,4-dichlorobenzoyl peroxide, dicumyl peroxide, and di-t-butyl peroxide. The examples of the crosslinking agent of acrylic rubber (acrylic polymer) include epoxy compounds, melamine compounds, and isocyanate compounds.

Examples of the cross-linked silicone rubber composition include addition cross-linked silicone rubber compositions containing organopolysiloxane with hydrosilyl groups (SiH groups), organopolysiloxane with vinyl groups, and addition reaction catalysts; addition cross-linked silicone rubber compositions containing organopolysiloxane with vinyl groups and addition reaction catalysts; and cross-linked silicone rubber compositions containing organopolysiloxane with SiCH₃ groups and organic peroxide curing agent.

The elastomer composition may further contain other components such as adhesive additives, silane coupling agents, and fillers as needed.

Preferably, the glass transition temperature of the cross-linked elastomer composition is, but not limited to, −40° C. or below, more preferably −50° C. or below in view of reducing the damage to the terminal of the inspection object. The glass transition temperature can be measured in compliance with JIS K 7095:2012.

Preferably, the storage modulus at 25° C. of the cross-linked elastomer composition is 1.0×10⁷ Pa or smaller, more preferably 1.0×10⁵ to 9.0×10⁶ Pa. The storage modulus of the cross-linked elastomer composition can be measured in compliance with JISK7244-1:1998/ISO6721-1:1994.

The glass transition temperature and storage modulus of the cross-linked elastomer composition may be adjusted by the composition of the elastomer composition.

Through hole 12 makes up hollow 12′ with conductive layer 13 held at its inner wall surface. In this manner, the flexibility of insulating layer 11 is increased to increase the ease of the elastic deformation in the thickness direction of insulating layer 11.

The axis direction of through hole 12 may be approximately parallel to the thickness direction of insulating layer 11 (for example, the angle with respect to the thickness direction of insulating layer 11 is 100 or smaller), or may be inclined with respect to the thickness direction of insulating layer 11 (for example, the angle with respect to the thickness direction of insulating layer 11 is greater than 100 and equal to or smaller than 50°, preferably 20 to 45°). In the present embodiment, the axis direction of through hole 12 is approximately parallel to the thickness direction of insulating layer 11 (see FIG. 1). Note that the axis direction is the direction of the line connecting the centers of gravity (or centers) of the opening on first surface 11a side and the opening on second surface 11b side of through hole 12.

The shape of the opening of through hole 12 (or the shape in the cross-section orthogonal to the axis direction of through hole 12) at first surface 11a is not limited, and may be rectangles and other polygons, for example. In the present embodiment, the shape of the opening of through hole 12 at first surface 11a is a circular shape (see FIGS. 1A and 1). In addition, the shape of the opening on first surface 11a side and the shape of the opening on second surface 11b side of through hole 12 may be the same or different, but preferably the same in view of the stability of the connection to the electronic device as the measurement target.

At first surface 11a, center of gravity c2 of the opening of through hole 12 (or hollow 12′) is separated from center of gravity c1 of conductive layer 13 continuously disposed around the opening (see FIG. 2A). Here “center of gravity c1 of conductive layer 13” is the center of gravity of conductive layer 13 when it is assumed that the opening of through hole 12 (or hollow 12′) is not provided, i.e., the center of gravity of the region defined by the outer edge of conductive layer 13. For example, in the case where the plan shape of conductive layer 13 is square, center of gravity c1 of conductive layer 13 is the center of the square (the intersection of diagonals) regardless of the position of the opening of through hole 12. The pushing load of the terminal of the inspection object is most likely to be exerted on center of gravity c1 of conductive layer 13. By separating center of gravity c2 of the opening of through hole 12 from center of gravity c1 of conductive layer 13 by a given distance or more, the pushing load exerted on through hole 12 can be reduced.

At first surface 11a, the distance (separation distance D) between center of gravity c2 of the opening of through hole 12 and center of gravity c1 of conductive layer 13 is not limited as long as the pushing load exerted on through hole 12 can be reduced. To be more specific, preferably, separation distance D is L/3 or greater, more preferably L/2 or greater, still more preferably L/1.5 or greater where L represents the length of the opening of through hole 12 on straight line m passing through center of gravity c2 of the opening of through hole 12 and center of gravity c1 of conductive layer 13 at first surface 11a, while it depends on the relative size of the opening of through hole 12 (with respect to conductive layer 13) at first surface 11a, for example. The upper limit value of separation distance D is not limited as long as the conduction of conductive layer 13 is not impaired. More specifically, preferably, the outer edge of the opening of through hole 12 is not in contact with the outer edge of conductive layer 13 (there is a gap between the outer edge of the opening of through hole 12 and the outer edge of conductive layer 13). That is, preferably, the opening of through hole 12 is completely surrounded by conductive layer 13 at first surface 11a (see FIG. 2A).

Preferably, length L of the opening of through hole 12 on straight line m passing through center of gravity c2 of the opening of through hole 12 and center of gravity c1 of conductive layer 13 may be, but not limited to, a range equivalent to the circle equivalent diameter of the opening of through hole 12 at first surface 11a, e.g., 1 to 330 m, more preferably 2 to 200 m, still more preferably 5 to 150 m (see FIG. 2A).

Length L of the opening of through hole 12 at first surface 11a and length L of the opening of through hole 12 at second surface 11b may be the same or different.

At first surface 11a, the opening of through hole 12 may encompass center of gravity c1 of conductive layer 13 (see FIG. 2B), or may not encompass center of gravity c1 of conductive layer 13 (see FIG. 2A). Preferably, the opening of through hole 12 does not encompass center of gravity c1 of conductive layer 13, i.e., the opening of through hole 12 is separated from center of gravity c1 of conductive layer 13 in view of more easily reducing the pushing load exerted on through hole 12 (see FIG. 2A).

Length L of the opening of through hole 12 (or the circle equivalent diameter of the opening of through hole 12) on straight line m of first surface 11a is set to a range within the region surrounded by outer edge of conductive layer 13. More specifically, preferably, the shape of the outer edge of conductive layer 13 at first surface 11a is quadrangle (see FIG. 2A). Preferably, when conductive layer 13 is divided by two straight lines intersecting at center of gravity c1 into four regions 13a with the same area at first surface 11a, the opening of through hole 12 is disposed within one region 13a (see FIG. 3A).

As described above, the range of the circle equivalent diameter of the opening of through hole 12 at first surface 11a may be the same range as length L of the opening of through hole 12 on straight line m. Note that the circle equivalent diameter of the opening of through hole 12 at first surface 11a is the circle equivalent diameter of the opening (the diameter of the true circle corresponding to the area of the opening) of through hole 12 as viewed along the thickness direction of insulating layer 11 from the first surface 11a side.

Center-to-center distance (pitch) p of the openings of the plurality of through holes 12 at first surface 11a is not limited, and may be set as necessary in accordance with the pitch of the terminal of the inspection object (see FIG. 3B). From the fact that the pitch of the terminal of the HBM (High Bandwidth Memory) as the inspection object is 55 m, and that the pitch of the terminal of PoP (Package on Package) is 400 to 650 m, center-to-center distance p of the openings of the plurality of through holes 12 may be 5 to 650 m, for example. More preferably, center-to-center distance p of the openings of the plurality of through holes 12 on first surface 11a side is 5 to 55 m in view of eliminating the necessity of the alignment (i.e., achieving alignment free) of the terminal of the inspection object. Center-to-center distance p of the openings of the plurality of through holes 12 on first surface 11a side is the minimum value of the center-to-center distance of the openings of the plurality of through holes 12 on first surface 11a side. The center of opening of through hole 12 is the center of gravity of the opening. In addition, center-to-center distance p of the openings of the plurality of through holes 12 may be constant or varied in the axis direction constant.

The positional relationship between center of gravity c2 of the opening of through hole 12 and center of gravity c1 of conductive layer 13, the shape and length L of the opening of through hole 12, center-to-center distance (pitch) p of the plurality of through holes 12 and the like at first surface 11a described above apply also to second surface 11b.

Preferably, the ratio (T/L) of the axial length of through hole 12 (that is, thickness T of insulating layer 11) and length L of the opening of through hole 12 on first surface 11a side is, but is not limited to, 3 to 40 (see FIG. 3B).

The thickness of insulating layer 11 need only be a value with which the insulation property at the non-conduction portion can be ensured, and is not limited. Preferably, the thickness of insulating layer 11 is 40 to 700 m, more preferably 100 to 400 m, for example.

### 1-2. Conductive Layer 13

Conductive layer 13 is disposed in a manner corresponding to through hole 12 (or hollow 12′) (see FIG. 1). More specifically, conductive layer 13 is continuously disposed at inner wall surface 12c of through hole 12, around the opening of through hole 12 on first surface 11a, and around the opening of through hole 12 on second surface 11b. Conductive layer 13 in the unit surrounded by the broken line functions as one conductive path (see FIGS. 1A and 1). Adjacent two conductive layers 13 are insulated by first groove part 14 and second groove part 15 (see FIG. 1).

Preferably, the shape of the outer edge of conductive layer 13 defined by first groove part 14 (or second groove part 15) at first surface 11a (or second surface 11b) is, but not limited to, quadrangle from a view point of workability and the like. The quadrangle includes square, rectangular, parallelogram, and rhombus. In the present embodiment, the shape of the outer edge of conductive layer 13 at first surface 11a (or second surface 11b) is square (see FIG. 2A).

The size of conductive layer 13 defined by first groove part 14 (or second groove part 15) at first surface 11a (or second surface 11b) need only be a size within which one or more openings of through holes 12 are accommodated.

The volume resistivity of the material of conductive layer 13 need only be a value with which sufficient conduction can be obtained, and is not limited. Preferably, the volume resistivity of the material of conductive layer 13 is 1.0×10⁻⁴ Ω·m or smaller, more preferably 1.0×10⁻⁶ to 1.0×10⁻⁹ Ω·m. The volume resistivity of the material of conductive layer 13 can be measured by the method described in ASTM D 991.

The volume resistivity of the material of conductive layer 13 need only satisfy the above-mentioned range. Examples of the material of conductive layer 13 include copper, gold, platinum, silver, nickel, tin, iron, metal materials of their alloys, and carbon materials such as carbon black.

The thickness of conductive layer 13 need only be within a range in which a sufficient conduction is achieved, and the plurality of conductive layers 13 does not make contact with each other with first groove part 14 or second groove part 15 therebetween when pressed in the thickness direction of insulating layer 11. More specifically, preferably, the thickness of conductive layer 13 is smaller than the width and depth of first groove part 14 and second groove part 15.

More specifically, the thickness of conductive layer 13 may be 0.1 to 5 m. When the thickness of conductive layer 13 has a given value or greater, sufficient conduction is easily achieved. When the thickness has a given value or smaller, through hole 12 is less closed, and the terminal of the inspection object is less damaged by the contact with conductive layer 13. Note that thickness t of conductive layer 13 is the thickness in the direction parallel to the thickness direction of insulating layer 11 on first surface 11a and second surface 11b, while it is the thickness in the direction orthogonal to the thickness direction of insulating layer 11 on inner wall surface 12c of through hole 12 (see FIG. 3).

As described above, anisotropic conductive sheet 10 includes the plurality of hollows 12′ surrounded by the plurality of conductive layers 13 (and derived from the plurality of through holes 12).

The shape of hollow 12′ in the cross-section orthogonal to the axis direction is the same as the shape of through hole 12 in the cross-section orthogonal to the axis direction. That is, the shape of the opening of hollow 12′ surrounded by conductive layer 13 at first surface 11a corresponds to the shape of the opening of through hole 12.

The length of the opening of hollow 12′ on straight line m at first surface 11a is substantially the same as length L of the opening of through hole 12 on straight line m. More specifically, the length of the opening of hollow 12′ on straight line m is obtained by subtracting the thickness of conductive layer 13 from length L of the opening of through hole 12 on straight line m, and may be 1 to 330 m, for example.

### 1-3. First Groove Part 14 and Second Groove Part 15

First groove part 14 and second groove part 15 are grooves (valleys) formed in one surface and the other surface of anisotropic conductive sheet 10. More specifically, first groove part 14 is disposed between the plurality of conductive layers 13 on first surface 11a to insulate therebetween. Second groove part 15 is disposed between the plurality of conductive layers 13 on second surface 11b to insulate therebetween.

The cross-sectional shape of first groove part 14 (or second groove part 15) in the direction orthogonal to the extending direction may be, but not limited to, a quadrangular shape, a semicircular shape, a U-shape, or V-shape. In the present embodiment, the cross-sectional shape of first groove part 14 (or second groove part 15) is quadrangle.

Preferably, width w and depth d of first groove part 14 (or second groove part 15) are set to a value with which one conductive layer 13 and the other conductive layer 13 do not make contact with each other with first groove part 14 (or second groove part 15) therebetween (see FIG. 3B) when anisotropic conductive sheet 10 is pressed in the thickness direction.

More specifically, when anisotropic conductive sheet 10 is pressed in the thickness direction, one conductive layer 13 and the other conductive layer 13 are likely to approach and touch each other with first groove part 14 (or second groove part 15) therebetween. As such, preferably, width w of first groove part 14 (or second groove part 15) is greater than the thickness of conductive layer 13, and is 2 to 40 times the thickness of conductive layer 13.

Width w of first groove part 14 (or second groove part 15) is a maximum width in the direction orthogonal to the direction in which first groove part 14 (or second groove part 15) is extended at first surface 11a (or second surface 11b) (see FIG. 3B).

Depth d of first groove part 14 (or second groove part 15) may be the same as or greater than the thickness of conductive layer 13. Specifically, the deepest part of first groove part 14 (or second groove part 15) may be located at first surface 11a of insulating layer 11 or inside insulating layer 11. In particular, preferably, depth d of first groove part 14 (or second groove part 15) is greater than the thickness of conductive layer 13, and is 1.5 to 20 times or more the thickness of conductive layer 13 from the viewpoint of easily setting the range with which one conductive layer 13 and the other conductive layer 13 do not make contact with each other with first groove part 14 (or second groove part 15) therebetween (see FIG. 3B).

Depth d of first groove part 14 (or second groove part 15) is the depth to the deepest part from the surface of conductive layer 13 in the direction parallel to the thickness direction of insulating layer 11 (see FIG. 3B).

Width w and depth d of first groove part 14 and second groove part 15 may be the same or different.

### 1-4. Effect

Anisotropic conductive sheet 10 of the present embodiment includes the plurality of hollows 12′ surrounded by conductive layer 13 (hollows originating from through hole 12). Further, in electrical inspection, normally, the terminal of the inspection object is pressed against center of gravity c1 of conductive layer 13. As described above, at first surface 11a, center of gravity c2 of the opening of through hole 12 (or hollow 12′) is separated from center of gravity c1 of conductive layer 13 (see FIG. 1A). In this manner, the pushing load exerted on through hole 12 (or hollow 12′) can be reduced in comparison with a known anisotropic conductive sheet in which the center of gravity of the opening of the through hole is aligned with the center of gravity of the conductive layer. In this manner, even when pressurization or depressurization through pushing are repeated in electrical inspection, cracking and peeling of conductive layer 13 at the inner wall surface of through hole 12 due to the pushing load can be suppressed, and the electrical connection can be stably performed.

### 2. Manufacturing Method of Anisotropic Conductive Sheet

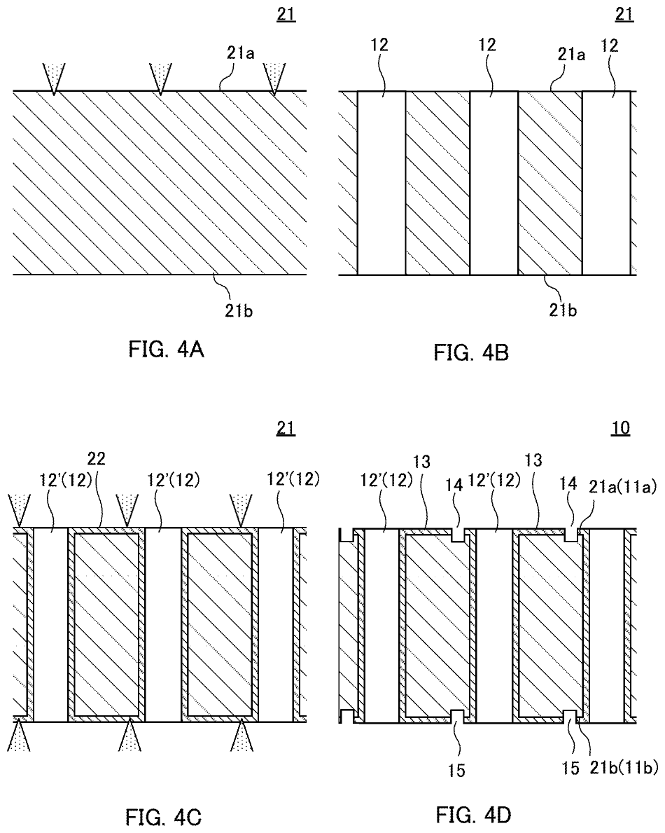

FIGS. 4A to 4D are schematic cross-sectional views illustrating a manufacturing method of anisotropic conductive sheet 10 according to the present embodiment.

Anisotropic conductive sheet 10 according to the present embodiment is manufactured through Step 1) of preparing insulating sheet 21 (see FIG. 4A), Step 2) of forming the plurality of through holes 12 in insulating sheet 21 (see FIGS. 4A and 4B), Step 3) of forming one continuous conductive layer 22 in the surface of insulating sheet 21 in which the plurality of through holes 12 is formed (see FIG. 4C), and Step 4) of forming first groove part 14 and second groove part 15 in first surface 21a and second surface 21b of insulating sheet 21 to form the plurality of conductive layers 13 (see FIG. 4D), for example.

### Step 1)

First, insulating sheet 21 is prepared (see FIG. 4A). Insulating sheet 21 is a sheet containing the above-mentioned cross-linked elastomer composition, for example.

### Step 2)

Next, the plurality of through holes 12 is formed in insulating sheet 21 (see FIGS. 4A and 4B).

Through hole 12 may be formed by any method. For example, it may be performed by a method of mechanically forming holes (such as pressing and punching), a laser processing method, or the like. In particular, preferably, through hole 12 is formed by a laser processing method from the viewpoint of enebling minute and highly accurate formation of through hole 12.

For the laser, excimer lasers, femtosecond lasers, carbon dioxide lasers, YAG lasers and the like that can accurately make holes in resins may be used. In particular, it is preferable to use excimer lasers or femtosecond lasers.

Note that in laser processing, the opening diameter of through hole 12 tends increase at the laser irradiation surface of insulating layer 11 where the laser irradiation time is longest. Specifically, a tapered shape with the opening diameter increasing from the inside of insulating layer 11 toward the laser irradiation surface tends to be formed. From the viewpoint of reducing such a tapered shape, laser processing may be performed by using insulating sheet 21 having a sacrificial layer (not illustrated in the drawing) in the surface to be irradiated with laser. The laser processing method for insulating sheet 21 including the sacrificial layer can be performed by a method similar to that disclosed in WO2007/23596.

### Step 3)

Next, one continuous conductive layer 22 is formed in the entire surface of insulating sheet 21 in which the plurality of through holes 12 is formed (see FIG. 4C). More specifically, in insulating sheet 21, conductive layer 22 is continuously formed at inner wall surface 12c of the plurality of through holes 12, and first surface 21a and second surface 21b around the opening thereof.

Conductive layer 22 may be formed by any method, but it is preferable to use plating methods (such as electroless plating methods and lectrolytic plating methods) from the viewpoint of enabling the formation of conductive layer 22 with a thin and uniform thickness without closing through hole 12.

### Step 4)

Next, first groove part 14 and second groove part 15 are formed at first surface 21a and second surface 21b, respectively of insulating sheet 21 to form the plurality of conductive layers 13 (see FIG. 4D). In this manner, conductive layer 22 can be set to the plurality of conductive layers 13 provided for respective through holes 12 (see FIG. 1).

The plurality of first groove parts 14 and second groove parts 15 may be formed by any method. For example, it is preferable to use laser processing methods for forming the plurality of first groove parts 14 and the plurality of second groove parts 15. In the present embodiment, the plurality of first groove parts 14 (or the plurality of second groove parts 15) may be formed in a grid at first surface 11a (or second surface 11b).

The manufacturing method of anisotropic conductive sheet 10 according to the present embodiment may further include other steps than the steps described above as necessary. For example, Step 5) of preprocessing for increasing the ease of formation of conductive layer 22 may be performed between Step 2) and Step 3).

### Step 5)

It is preferable to perform a desmear treatment (preprocessing) for increasing the ease of formation of conductive layer 22 for insulating sheet 21 in which the plurality of through holes 12 is formed.

The desmear treatment is a treatment for removing the smear generated by the laser processing, and is preferably an oxygen plasma treatment. For example, in the case where insulating sheet 21 is composed of a cross-linked silicone-based elastomer composition, the oxygen plasma treatment of insulating sheet 21 allows not only for ashing/etching, but also for formation of a silica film through oxidation of the silicone surface. By forming a silica film, the plating solution can easily penetrate into through hole 12, and the adhesion between conductive layer 22 and the inner wall surface of through hole 12 can be increased.

The oxygen plasma treatment can be performed by using plasma ashers, radio frequency plasma etching apparatuses, micro wave plasma etching apparatuses, for example.

Preferably, the obtained anisotropic conductive sheet can be used for electrical inspection.

### 3. Electrical Inspection Apparatus and Electrical Inspection Method

### Electrical Inspection Apparatus

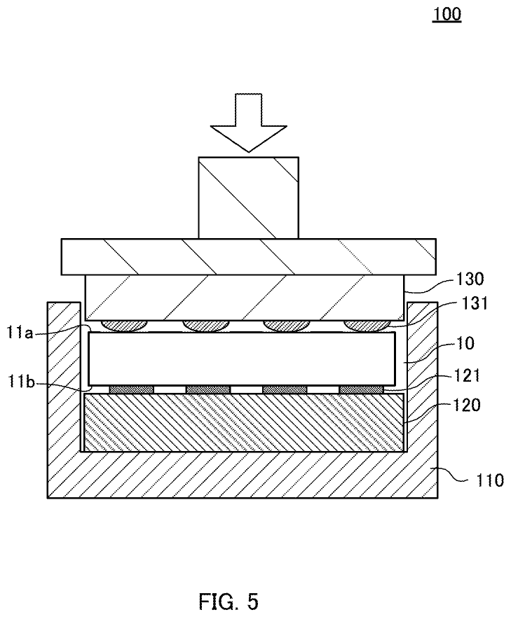

FIG. 5 is a sectional view illustrating an example of electrical inspection apparatus 100 used for the electrical inspection method according to the present embodiment.

Electrical inspection apparatus 100 uses anisotropic conductive sheet 10 of FIG. 1, and inspects the electrical characteristics (such as conduction) between terminals 131 (measurement points) of inspection object 130, for example. Note that in the drawing, inspection object 130 is also illustrated for the purpose of describing the electrical inspection method.

As illustrated in FIG. 5, electrical inspection apparatus 100 includes holding container (socket) 110, inspection substrate 120, and anisotropic conductive sheet 10.

Holding container (socket) 110 is a container for holding inspection substrate 120, anisotropic conductive sheet 10 and the like.

Inspection substrate 120 is disposed inside holding container 110, and includes a plurality of electrodes 121 facing the measurement points of inspection object 130 at the surface facing inspection object 130.

Anisotropic conductive sheet 10 is disposed on the surface where electrode 121 of inspection substrate 120 is disposed such that the electrode 121 and conductive layer 13 on second surface 11b side in anisotropic conductive sheet 10 make contact with each other.

Examples of inspection object 130 include, but not limited to, various semiconductor devices (semiconductor packages) such as HBMs and PoPs, electronic components, and printed boards. In the case where inspection object 130 is a semiconductor package, the measurement point may be a bump (terminal). In addition, in the case where inspection object 130 is a printed board, the measurement point may be a measuring land and a component mounting land provided in the conductive pattern.

### Electrical Inspection Method

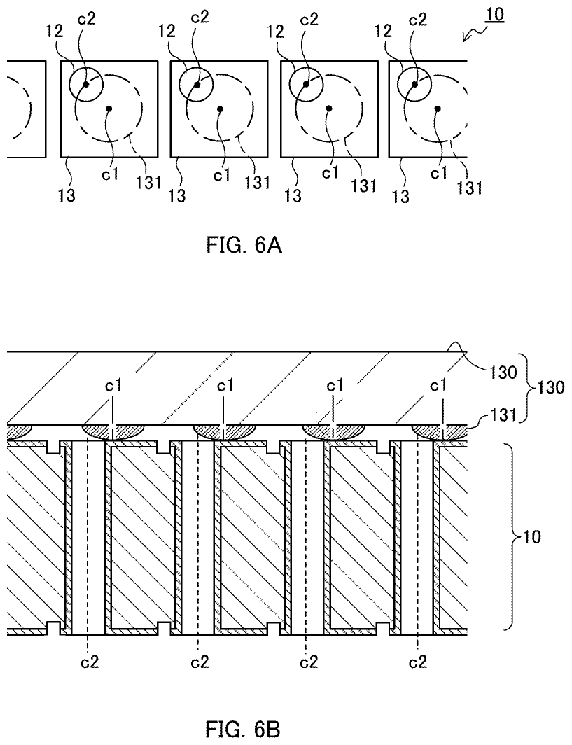

FIG. 6A is a partially enlarged plan view illustrating an electrical inspection method according to the present embodiment, and FIG. 6B is a partially enlarged sectional view corresponding to FIG. 6A.

The electrical inspection method according to the present embodiment includes Step 1) of preparing anisotropic conductive sheet 10, and Step 2) of placing inspection object 130 on first surface 11a of anisotropic conductive sheet 10 to electrically connect terminal 131 of inspection object 130 and the conductive layer of anisotropic conductive sheet 10.

At Step 2), more specifically, inspection substrate 120 including electrode 121 and inspection object 130 are stacked with anisotropic conductive sheet 10 therebetween, and electrode 121 of inspection substrate 120 and terminal 131 of inspection object 130 are electrically connected to each other with anisotropic conductive sheet 10 therebetween (see FIG. 5).

Then, for the purpose of facilitating the sufficient conduction of electrode 121 of inspection substrate 120 and terminal 131 of inspection object 130 with anisotropic conductive sheet 10 therebetween, a pressure may be exerted by pressing inspection object 130, and they may be brought into contact with each other under heating atmosphere.

In the present embodiment, inspection object 130 is disposed such that the center of terminal 131 of inspection object 130 (where the load is most exerted) is located in the vicinity of center of gravity c1 of conductive layer 13 at first surface 11a of anisotropic conductive sheet 10 (see FIG. 6B). Then, at first surface 11a of anisotropic conductive sheet 10, center of gravity c2 of the opening of through hole 12 is separated from center of gravity c1 of conductive layer 13 (where the pushing load of inspection object 130 is largely exerted). In this manner, even when a pushing load is exerted by inspection object 130, the pressure exerted on through hole 12 can be reduced. In this manner, even when pressurization and depressurization are repeated, the crack and peeling of conductive layer 13 on the inner wall surface of through hole 12 can be suppressed, and terminal 131 of inspection object 130 and conductive layer 13 can be stably electrically connected.

### Modifications

Note that while the present embodiment is described with an example of anisotropic conductive sheet 10 illustrated in FIG. 1, the present invention is not limited to this.

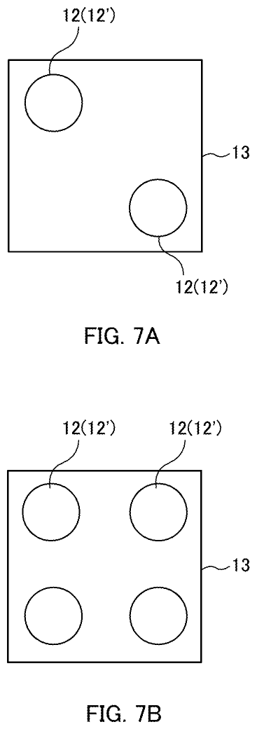

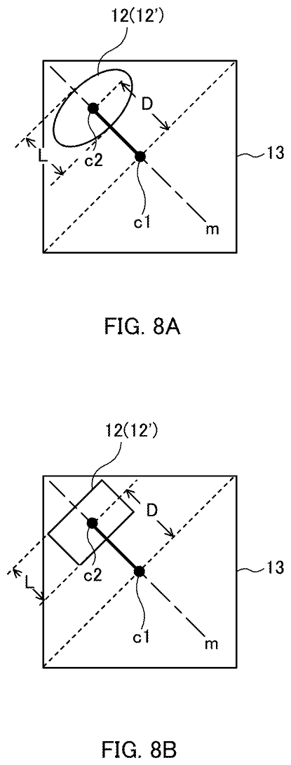

FIGS. 7A and 7B are partially enlarged plan views of a region around through hole 12 at first surface 11a of anisotropic conductive sheet 10 according to a modification. FIGS. 8A and 8B are partially enlarged plan views illustrating a modification of a shape of an opening of through hole 12.

For example, while an example in which one through hole 12 is disposed for each conductive layer 13 is described in the present embodiment, this is not limitative, and two or more through holes 12 may be disposed for each conductive layer 13 (FIGS. 7A and 7B). For example, the plurality of conductive layers 13 may be respectively disposed in a manner corresponding to at least some of the plurality of through holes 12, and some other through hole may be further disposed in the plurality of conductive layers 13. In this case, it suffices that at least one of the two or more through holes 12 meets the relationship of separation distance D of center of gravity c2 of the opening of through hole 12 and center of gravity c1 of conductive layer 13.

In addition, while an example in which the shape of the opening of through hole 12 is circle is described in the present embodiment, this is not limitative, and the shape may be ellipse (see FIG. 8A) or rectangular (see FIG. 8B).

In this case, preferably, length L of the opening of through hole 12 on straight line m passing through center of gravity c2 of the opening of through hole 12 and center of gravity c1 of conductive layer 13 at first surface 11a corresponds to the minor axis of the ellipse of the opening of through hole 12 or the short side of the rectangular (FIGS. 8A and 8B). Specifically, in the case where the part of length L of the opening of through hole 12 is along the minor axis or the short side of the shape of the opening of through hole 12, separation distance D of center of gravity c2 of the opening of through hole 12 and center of gravity c1 of the conductive layer on first surface 11a can be increased in comparison with the case where it is along the major axis or the long side, and thus the pushing load exerted on conductive layer 13 on the inner wall surface of through hole 12 can be further reduced.

In addition, while an example in which insulating layer 11 is composed of an elastic body layer containing a cross-linked elastomer composition is described in the present embodiment, this is not limitative, and another layer such as a heat-resistant resin layer may be further provided as long as elastic deformation can be achieved.

Preferably, the heat-resistant resin composition making up the heat-resistant resin layer has a higher glass transition temperature or storage modulus than that of the cross-linked elastomer composition making up the elastic body layer. For example, preferably, the glass transition temperature of the heat-resistant resin composition is 150° C. or above, more preferably 150 to 500° C. because the electrical inspection is performed at approximately −40 to 150° C. The glass transition temperature of the heat-resistant resin composition can be measured by the method described above.

Examples of the resin contained in the heat-resistant resin composition include engineering plastics such as polyamide, polycarbonate, polyarylate, polysulfone, polyether sulfone, polyphenylene sulfide, polyetheretherketone, polyimide, and polyetherimide, and acrylic resins, urethane resins, epoxy resins, and olefin resins.

In the case where the heat-resistant resin layer is disposed on the surface of anisotropic conductive sheet 10, it is preferable that depth d of first groove part 14 (or second groove part 15) be greater than the thickness of the heat-resistant resin layer. When first groove part 14 (or the depth of second groove part 15) is greater than the thickness of the heat-resistant resin layer, the heat-resistant resin layer can be completely divided, and surrounding conductive layer 13 can be prevented from being pushed together when pushed with inspection object 130 on it.

In addition, while an example in which the plurality of conductive layers 13 and the plurality of second groove parts 15 are disposed also at second surface 11b of anisotropic conductive sheet 10 is described in the present embodiment, this is not limitative.

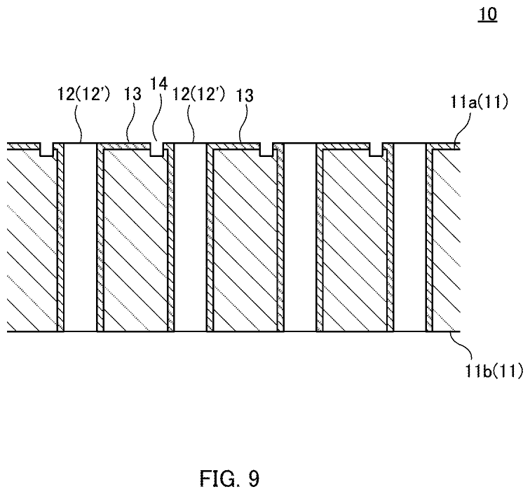

FIG. 9 is a partially enlarged sectional view of anisotropic conductive sheet 10 according to a modification. As illustrated in FIG. 9, anisotropic conductive sheet 10 may not include second groove part 15 in a case where conductive layer 13 is not provided on second surface 11b.

Note that in the electrical inspection method according to the above-described embodiment, the anisotropic conductive sheet in which center of gravity c2 of the opening of through hole 12 (or hollow 12′) is separated from center of gravity c1 of conductive layer 13 at first surface 11a is used and thus inspection object 130 is disposed on first surface 11a such that the center of gravity of terminal 131 of inspection object 130 is separated from center of gravity c1 of conductive layer 13, but this is not limitative.

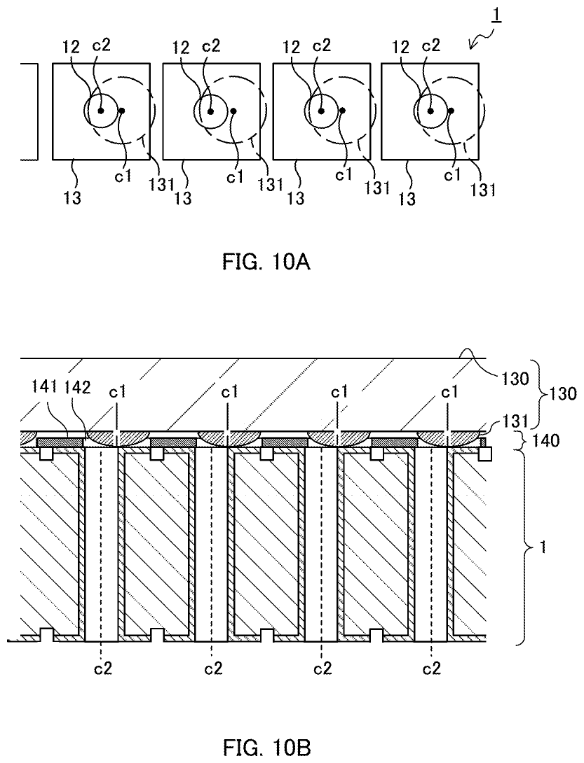

FIG. 10A is a partially enlarged plan view illustrating an electrical inspection method according to a modification, and FIG. 10B is a partially enlarged sectional view corresponding to FIG. 10A. As illustrated in FIGS. 10A and 10B, it is possible to use anisotropic conductive sheet 1 in which center of gravity c2 of the opening of through hole 12 is not separated from center of gravity c1 of conductive layer 13 (center of gravity c2 of the opening of through hole 12 coincides with center of gravity c1 of conductive layers 13) at first surface 11a. That is, inspection object 130 may be disposed on first surface 11a of anisotropic conductive sheet 1 such that center of gravity c1 of terminal 131 of inspection object 130 is separated (shifted) from center of gravity c2 of the opening of through hole 12.

In this case, guide member 140 may be used from the viewpoint of increasing the positional accuracy of terminal 131 of inspection object 130 (see FIG. 10B). Guide member 140 includes base material 141, and a plurality of terminal holes 142 disposed in it. Then, it is possible to perform a step of disposing guide member 140 on first surface 11a such that the center of gravity of terminal hole 142 of guide member 140 is separated from center of gravity c1 of conductive layer 13 at first surface 11a of anisotropic conductive sheet 1 prepared at Step 1). Thereafter, at Step 2), it suffices to insert terminal 131 of inspection object 130 to terminal hole 142 of guide member 140 so as to electrically connect terminal 131 of inspection object 130 and conductive layer 13.

In addition, while the anisotropic conductive sheet is used for electrical inspection is described in the present embodiment, this is not limitative, and the anisotropic conductive sheet may be used for the electrical connection between two electronic members, such as electrical connection between a glass substrate and a flexible printed board, and electrical connection between a substrate and an electronic component mounted on the substrate.

This application is entitled to and claims the benefit of Japanese Patent Application No. 2020-206277 filed on Dec. 11, 2020, the disclosure each of which including the specification, drawings and abstract is incorporated herein by reference in its entirety.

### INDUSTRIAL APPLICABILITY

According to the present invention, it is possible to provide an anisotropic conductive sheet and an electrical inspection method using the same with which cracks and peeling of the conductive layer can be suppressed even when pressurization and depressurization through pushing are repeated, and favorable conductivity can be maintained.

### REFERENCE SIGNS LIST

10 Anisotropic conductive sheet
11 Insulating layer
11a First surface
11b Second surface
12 Through hole
13 Conductive layer
14 First groove part
15 Second groove part
21 Insulating sheet
22 Conductive layer
100 Electrical inspection apparatus
110 Holding container
120 Inspection substrate
121 Electrode
130 Inspection object
131 Terminal (of inspection object)
C1 Center of gravity (of conductive layer)
C2 Center of gravity (of through hole)
D Separation distance
L Length of through hole opening

1. An anisotropic conductive sheet comprising:
an insulating layer including a first surface located on one side in a thickness direction, a second surface located on another side, and a plurality of through holes extending between the first surface and the second surface;
a plurality of conductive layers each disposed at each of at least some of the plurality of through holes such that the plurality of conductive layers is continuous at an inner wall surface of the each of at least some of the plurality of through holes and around an opening of the each of at least some of the plurality of through holes on the first surface; and
a plurality of first groove parts disposed on the first surface between the plurality of conductive layers, and configured to insulate the plurality of conductive layers, wherein
on the first surface, a center of gravity of an opening of each of the plurality of through holes is separated from a center of gravity of a conductive layer of the plurality of conductive layers continuously disposed around the opening.

2. The anisotropic conductive sheet according to claim 1, wherein when L represents a length of the opening of each of the plurality of through holes on a straight line passing through the center of gravity of the opening of each of the plurality of through holes and a center of gravity of each of the plurality of conductive layers at the first surface, a distance between the center of gravity of the opening of each of the plurality of through holes and the center of gravity of each of the plurality of conductive layers at the first surface is L/3 or greater.

3. The anisotropic conductive sheet according to claim 1, wherein at the first surface, the opening of each of the plurality of through holes is completely surrounded by each of the plurality of conductive layers.

4. The anisotropic conductive sheet according to claim 1, wherein at the first surface, the opening of each of the plurality of through holes is separated from a center of gravity of each of the plurality of conductive layers.

5. The anisotropic conductive sheet according to claim 1, wherein when L represents a length of the opening of each of the plurality of through holes on a straight line passing through the center of gravity of the opening of each of the plurality of through holes and a center of gravity of each of the plurality of conductive layers at the first surface, the length L of the opening of each of the plurality of through holes is 5 to 150 μm.

6. The anisotropic conductive sheet according to claim 1, wherein an outer edge of each of the plurality of conductive layers at the first surface has a quadrangular shape.

7. The anisotropic conductive sheet according to claim 6, wherein when each of the plurality of conductive layers is divided by two straight lines intersecting at a center of gravity of each of the plurality of conductive layers into four regions with the same area at the first surface, each of the plurality of through holes is provided within one of the regions.

8. The anisotropic conductive sheet according to claim 1, wherein two or more through holes of the plurality of through holes are disposed in each of the plurality of conductive layers.

9. The anisotropic conductive sheet according to claim 1,
wherein the plurality of conductive layers is further disposed around the plurality of through holes on the second surface, and
wherein the anisotropic conductive sheet further includes a plurality of second groove parts disposed on the second surface between the plurality of conductive layers and configured to insulate the plurality of conductive layers.

10. An electrical inspection method comprising:
preparing an anisotropic conductive sheet, the anisotropic conductive sheet including:
an insulating layer including a first surface located on one side in a thickness direction, a second surface located on another side, and a plurality of through holes extending between the first surface and the second surface,
a plurality of conductive layers each disposed at each of at least some of the plurality of through holes such that the plurality of conductive layers is continuous at an inner wall surface of the each of at least some of the plurality of through holes and around an opening of the each of at least some of the plurality of through holes on the first surface, and
a plurality of first groove parts disposed on the first surface between the plurality of conductive layers, and configured to insulate the plurality of conductive layers; and
electrically connecting a terminal of an inspection object and each of the plurality of conductive layers by disposing the inspection object on the first surface such that a center of gravity of the terminal of the inspection object is separated from a center of gravity of each of the plurality of conductive layers in plan view.

11. The electrical inspection method according to claim 10, further comprising:
disposing a guide member including a base material and a plurality of terminal holes disposed in the base material on the first surface such that a center of gravity of each of the plurality of terminal holes is separated from the center of gravity of each of the plurality of conductive layers at the first surface, wherein
the electrically connecting includes inserting the terminal of the inspection object to each of the plurality of terminal holes to electrically connect the terminal of the inspection object and each of the plurality of conductive layers.

12. The electrical inspection method according to claim 10, wherein in the anisotropic conductive sheet, a center of gravity of an opening of each of the plurality of through holes is separated from the center of gravity of each of the plurality of conductive layers at the first surface.
